(19) United States
(12) Patent Application Publication
(10) Pub. No.: US 2009/0026578 A1
(43) Pub. Date: Jan. 29, 2009

(54) Vertical NPN Transistor Fabricated in a CMOS Process With Improved Electrical Characteristics

(75) Inventors: Schyi-yi Wu, San Jose, CA (US); Martin Alter, Los Altos, CA (US)

Correspondence Address: PATENT LAW GROUP LLP, 2635 NORTH FIRST STREET, SUITE 223, SAN JOSE, CA, 95134, US

(73) Assignee: MICREL, INC., San Jose, CA (US)

(21) Appl. No.: 11/829,802

(22) Filed: Jul. 27, 2007

(51) Int. Cl. H01L 29/732; H01L 21/331

(52) U.S. Cl. 257/592; 438/350; 257/E21.375; 257/E29.184

(57) ABSTRACT

A vertical NPN bipolar transistor includes a P-type semiconductor structure, an N-well as the collector, a P-Base region in the N-well and an N-type region as the emitter. The transistor further includes P-type region formed in the P-Base region and underneath the field oxide layer where the P-type region has a doping concentration higher than the P-base region. The P-type region functions to inhibit the lateral parasitic bipolar action so that the transistor action is confined to the intrinsic base region vertically underneath the emitter. In one embodiment, the P-type region is a boron field doping region. The boron field doping region can be the same field doping region used to form channel stops for NMOS transistors in a CMOS fabrication process.

### FIELD OF THE INVENTION

The invention relates to a fabrication process for vertical NPN bipolar transistors and, in particular, to a method and structure for forming vertical NPN bipolar transistors in CMOS or BiCMOS fabrication processes.

### DESCRIPTION OF THE RELATED ART

Bipolar transistors are often fabricated along with MOS transistors in integrated circuits built using CMOS or BiCMOS fabrication processes. However, limitations exist in incorporating bipolar transistors in CMOS or BiCMOS fabrication processes. For instance, in conventional CMOS processes, often only PNP bipolar transistors are provided and vertical NPN bipolar transistors are usually not available. This is because the P-type base of the NPN bipolar transistor would require an additional masking step. On the other hand, PNP bipolar transistors can be made in a CMOS process by using the P− substrate as the collector, the N-well as the base and the P+ region as the emitter. Even when vertical NPN bipolar transistors are built in a BiCMOS fabrication process by using an additional P-base mask and implantation, the NPN bipolar transistors suffer from poor electrical characteristics such as low gain.

### SUMMARY OF THE INVENTION

According to one embodiment of the present invention, a vertical NPN bipolar transistor includes a P-type semiconductor structure, an N-well formed in the P-type semiconductor structure where the N-well forms the collector region, a first P-type region formed in the N-well and surrounded by a field oxide layer where the first P-type region forms the base region, a first N-type region formed in the first P-type region where the first N-type region is heavily doped and forms the emitter region, a second P-type region formed in the first P-type region and underneath the field oxide layer where the second P-type region has a doping concentration higher than the first P-type region, a third P-type region formed in the first P-type region where the third P-type region is heavily doped and forms the base contact region, and a second N-type region formed in the N-well where the second N-type region is heavily doped and forms the collector contact region.

In one embodiment, the second P-type region is a boron field doping region. The boron field doping region can be the same field doping region used to form channel stops for NMOS transistors in a CMOS fabrication process.

The present invention is better understood upon consideration of the detailed description below and the accompanying drawings.

### BRIEF DESCRIPTION OF THE DRAWINGS

FIG. 1 is a cross-sectional view of a vertical NPN bipolar transistor formed using a CMOS fabrication process including boron field doping according to one embodiment of the present invention.

FIG. 2 illustrates a portion of the boron field (BFLD) mask in an intermediate step of the CMOS fabrication process for fabricating the vertical NPN bipolar transistor of FIG. 1 according to one embodiment of the present invention.

FIG. 3 is a cross-sectional view of a NMOS transistor formed using the CMOS fabrication process of FIG. 1.

FIG. 4 illustrates another portion of the boron field (BFLD) mask in an intermediate step of the CMOS fabrication process for fabricating the NMOS transistor of FIG. 3 according to one embodiment of the present invention.

FIG. 5 is a plot illustrating the collector-to-emitter breakdown voltage (BVCEO) characteristics of a vertical NPN bipolar transistor fabricated in accordance with the present invention as compared to a conventional NPN bipolar transistor.

### DETAILED DESCRIPTION OF THE PREFERRED EMBODIMENTS

In accordance with the principles of the present invention, a vertical NPN bipolar transistor fabricated in a CMOS or BiCMOS fabrication process includes P-type field doping at the bird's beak of the field oxide layer surrounding the base region. That is, P-type field doping is introduced at the periphery of the base region to increase the P-type doping concentration along the bird's beak areas of the field oxide. The P-type field doping at the bird's beak regions of the field oxide has the effect of inhibiting undesirable lateral parasitic transistor action at the extrinsic base region under the field oxide. As a result, a vertical NPN bipolar transistor fabricated in a CMOS or a BiCMOS process with improved electrical characteristics is realized.

In one embodiment, the P-type field doping is the boron field doping used to form channel stops for NMOS transistors in a conventional CMOS fabrication process. Thus, the boron field doping process in the P-Wells of the NMOS transistors used in a conventional CMOS fabrication process is also used as the boron field doping in the N-Well of the vertical NPN bipolar transistors. Therefore, no additional processing steps are required to introduce the P-type field doping to the vertical NPN bipolar transistors.

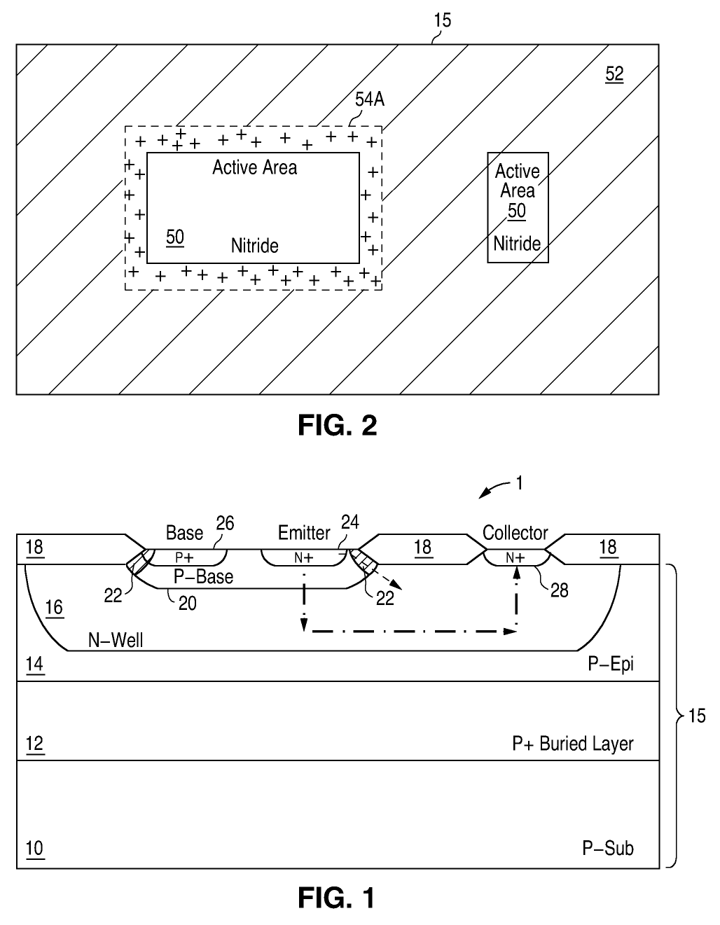

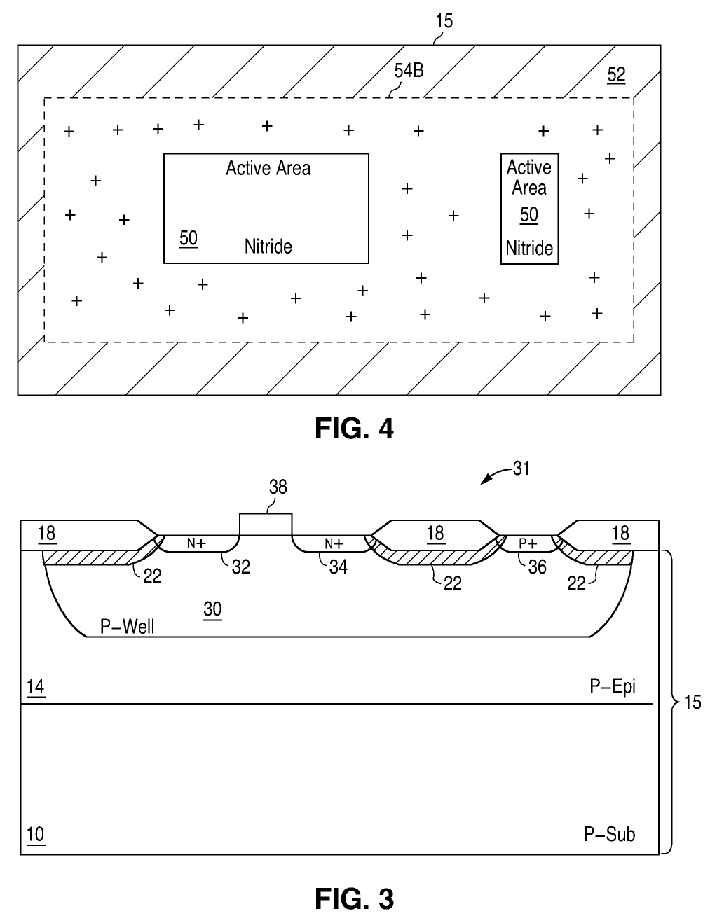

FIG. 1 is a cross-sectional view of a vertical NPN bipolar transistor formed using a CMOS fabrication process including boron field doping according to one embodiment of the present invention. Referring to FIG. 1, a vertical NPN bipolar transistor 1 (“NPN transistor 1”) is fabricated using a CMOS fabrication process. NPN transistor 1 is formed on a P-type substrate 10. A P+ buried layer 12 is formed in selected regions of the P-type substrate 10 and a P-type epitaxial layer (P-Epi) 14 is then formed on the substrate 10. On the same substrate 10, other transistors are also formed, such as NMOS transistor 31 as shown in FIG. 3. NMOS transistor 31 is formed in P-Epi 14 without any buried layer. The CMOS fabrication process for forming NPN transistor 1 and NMOS transistor 31 is described below with reference to FIGS. 1 and 3. In the following description, the P-type substrate 10 including the buried layer 12 and the P-Epi layer 14 will be collectively referred to as the semiconductor structure 15. Semiconductor structure 15 in the present embodiment is illustrative only and one of ordinary skill in the art would appreciate that other configurations for semiconductor structure 15 can be used in the CMOS fabrication process. For instance, semiconductor structure 15 may include only a P-type substrate.

After the P-Epi 14 is formed, masking and implantation steps are carried to define areas where N-Well 16 are to be formed and areas where P-Well 30 are to be formed. N-Well 16 serves as the collector of NPN transistor 1 while P-Well 30 severs as the body of NMOS transistor 31. After N-Well 16 and P-Well 30 are formed, a nitride mask is then deposited and patterned to define the active areas on the semiconductor structure 15. Active areas refer to areas where devices, such as transistors, resistors or capacitors, are to be formed. Areas on semiconductor structure 15 that are not active areas will be exposed to the field oxidation process where a field oxide layer will be grown.

For NPN transistor 1, the active areas include areas where the base, emitter and collector are to be formed. For NMOS transistor 31, the active areas include areas where the source, drain and channel regions are to be formed as well as the body contact diffusion regions. The patterned nitride mask defining the active areas on semiconductor structure 15 is shown in FIG. 2 for NPN transistor 1 and FIG. 4 for NMOS transistor 31. Referring to FIG. 2, patterned nitride mask 50 covers areas on semiconductor structure 15 where the base region and the collector region of NPN transistor 1 are to be formed. The emitter is formed in the base region. Referring to FIG. 3, patterned nitride mask 50 covers areas on semiconductor structure 15 where the drain, source and gate regions of NMOS transistor 31 are to be formed. The patterned nitride mask 50 also covers the area where the body contact diffusion region 36 is to be formed. Everywhere on semiconductor structure 15 not covered by patterned nitride mask 50 will be subjected to the field oxidation process.

Before the field oxidation takes place, the field doping process for forming channel stops in the field regions surrounding the NMOS transistors is carried out. More specifically, for NMOS transistor 31, boron (p-type) field doping is carried out to form P-type doped regions in P-Wells underneath the field oxide layer. The area where the field oxide layer is formed is referred to as the field regions. Thus, the P-type doped regions are formed in the field regions of the P-Well for NMOS transistor 31. The P-type doped regions in the P-Wells underneath the field oxide layer form channel stops for the NMOS transistor 31. Channel stops are used to enhance the isolation between adjacent MOS transistors by limiting the lateral conduction of the parasitic transistor between two neighboring transistors.

A field doping mask, also referred to as the boron field (BFLD) mask is used to define the areas of field regions receiving the field doping. In a CMOS fabrication process, field doping is only introduced in the P-Wells where NMOS transistors are to be formed. Thus, referring to FIG. 4, a boron field mask 52 is formed on semiconductor structure 15 having an opening 54B corresponding to P-Well 30 for NMOS transistor 31. Thus, areas exposed by boron field mask 52 and not covered by patterned nitride mask 50 will receive the boron field doping.

In accordance with the present invention, the boron field doping process performed for NMOS transistor 31 is also used to form P-type doped regions in the field region of N-well 16 for NPN transistor 1. The P-type doped regions thus formed, referred to as P-type field doped regions, function to inhibit the undesirable lateral parasitic base conduction in NPN transistor 1, as will be described in more detail below. Referring to FIG. 2, boron field mask 52 over NPN transistor 1 includes an opening 54A corresponding to the base region (P-Base 20) of NPN transistor 1. Thus, areas exposed by boron field mask 52 and not covered by patterned nitride mask 50 will receive the boron field doping.

The field doping process applies boron implantation using the boron field mask 52. Thus, all areas exposed by openings 54A and 54B will receive the boron implantation. However, patterned nitride mask 50 blocks the implantation and therefore, the boron field doping is self-aligned to the edges of the active areas 50. After the boron field implantation, mask 52 is removed and field oxidation process is carried out to grow a field oxide layer 18 everywhere on semiconductor structure 15 not covered by the patterned nitride mask 50. As a result of the field oxidation process, the boron field implantation is anneal and are pushed underneath the newly grown field oxide layer, forming P-type doped regions 22.

After field oxidation, the patterned nitride mask 50 is removed and subsequent processing steps are carried out to form the remaining structure of NPN transistor 1 and NMOS transistor 31. For NMOS transistor 31, gate oxidation is carried out and polysilicon is deposited and patterned to form a gate electrode 38. Heavily doped N+ regions 32 and 34, self-aligned to gate electrode 38 are formed as the source and drain regions of NMOS transistor 31. A heavily doped P+ region 36 is formed in P-Well 30 to form the electrical contact to the body of NMOS transistor 31. As thus formed, P-type field doped regions 22 are provided under the field oxide layer 18 and surrounding NMOS transistor 31 to act as a channel stop to improve the electrical isolation of NMOS transistor 31 from neighboring transistors.

For NPN transistor 1, a P-type implantation is carried out to form P-base region 20. P-base region 20 is a lightly doped P-type region and can have a doping concentration close to the doping concentration of the P-Wells. In one embodiment, P-base region 20 is doped to a resistivity of 2000-3000 ohms per square. A P+ region 26 (the base contact region) is formed in P-Base region 20 to form the electrical contact to the base of NPN transistor 1. An N+ region 24 is formed in P-Base region 20 to form the emitter of NPN transistor 1. Finally, an N+ region 28 (the collector contact region) is formed in N-Well 16 to form the electrical contact to the collector of NPN transistor 1.

As thus formed, NPN transistor 1 has an intrinsic base region being the base region underneath emitter 24. The normal electron flow through NPN transistor 1 is indicated by the dash-dot line and includes a path vertically down from emitter 24 through P-base 20 and into collector (N-Well) 16. The normal electron path continues through N-Well 16 and back up to N+ collector contact 28. However, NPN transistor 1 also includes an extrinsic base region at the field oxide edge (bird's beak) between the emitter 24 and N-Well 16. The extrinsic base region forms an undesirable parasitic NPN bipolar transistor. The parasitic transistor conduction through this extrinsic base region (indicated by the dotted line) has the tendency of lowering the breakdown voltage between the emitter and the collector of NPN transistor 1.

In accordance with the present invention, P-type doped regions 22 are formed at the field oxide edge of P-Base 20 using the field doping process. P-type doped regions 22 has a doping concentration that is higher than the P-base region 20 and thus has the effect of increasing the P-type concentration of P-Base 20 along the bird's beak of field oxide layer 18. The increased P-type concentration effectively lowers the gain (β) of the parasitic bipolar transistor at this extrinsic base region. The parasitic bipolar transistor action through this lateral path is thus inhibited so that the transistor action is confined to the intrinsic base region vertically underneath the emitter. The dominant conduction path of NPN transistor 1 remains the vertical path from emitter to base to collector as indicated by the dash-dot line which is the desired conduction path. The electrical characteristics of NPN transistor 1 are thereby significantly improved.

In the CMOS fabrication process described above, the boron field doping process for the NMOS transistors is also applied to form P-type field doped regions in the vertical NPN bipolar transistor. Thus, the same boron field mask is used for both field doping purposes and no additional processing step is required to introduce the P-type doped region for NPN transistor 1. It is important to note that for NMOS transistors, the P-type or boron field doping is introduced in the P-Wells. On the other hand, for vertical NPN bipolar transistors, the P-type or boron field doping is introduced in the P-base region formed in the N-Well. In conventional CMOS fabrication process, N-Wells do not receive the P-type field doping. Thus, the vertical NPN bipolar transistor 1 of the present invention is formed using P-type field doping in an N-Well which is not the common practice in conventional CMOS fabrication processes.

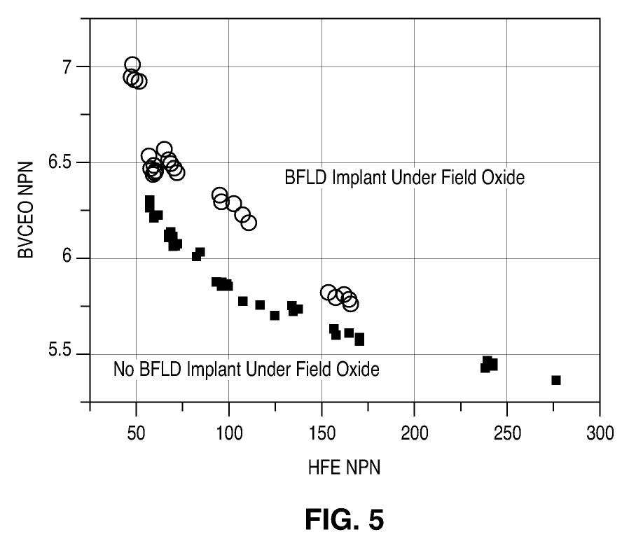

As thus constructed, the vertical NPN bipolar transistor achieves improved electrical characteristics. First, higher gain (β) is realized and the emitter-to-field-oxide spacing is reduced without sacrificing the emitter to collector breakdown voltage. Secondly, the breakdown voltage between the collector and the emitter of the transistor with the base open is also increased. FIG. 5 is a plot illustrating the collector-to-emitter breakdown voltage (BVCEO) characteristics of a vertical NPN bipolar transistor fabricated in accordance with the present invention as compared to a conventional NPN bipolar transistor. Referring to FIG. 5, for a given gain β of 100, at least 0.5 voltage BVCEO improvement can be observed. Furthermore, the breakdown voltage at β of 100 is greater than 6 volts as compared to the case of the conventional transistor where the breakdown voltage at β of 100 is less than 6 volts. In some applications, the maximum voltage applied to the bipolar transistors is 6 volts and therefore having the breakdown voltage greater than 6 volts provides the benefit of additional operational margin.

The above detailed descriptions are provided to illustrate specific embodiments of the present invention and are not intended to be limiting. Numerous modifications and variations within the scope of the present invention are possible. For example, in the above described embodiment, semiconductor structure 15 includes a P+ buried layer 12. P+ buried layer 12 is optional and may be omitted in other embodiments of the present invention. The present invention is defined by the appended claims.

We claim:

1. A vertical NPN bipolar transistor comprising:
a P-type semiconductor structure;
an N-well formed in the P-type semiconductor structure, the N-well forming the collector region;
a first P-type region formed in the N-well and surrounded by a field oxide layer, the first P-type region forming the base region;
a first N-type region formed in the first P-type region, the first N-type region being heavily doped and forming the emitter region;
a second P-type region formed in the first P-type region and underneath the field oxide layer, the second P-type region having a doping concentration higher than the first P-type region;
a third P-type region formed in the first P-type region, the third P-type region being heavily doped and forming the base contact region; and
a second N-type region formed in the N-well, the second N-type region being heavily doped and forming the collector contact region.

2. The vertical NPN bipolar transistor of claim 1, wherein the second P-type region comprises a boron field doping region.

3. The vertical NPN bipolar transistor of claim 2, wherein the semiconductor structure comprises an NMOS transistor formed in a P-well formed in the semiconductor structure, the boron field doping region being formed in the P-well and underneath the field oxide layer to act as a channel stop for the NMOS transistor.

4. The vertical NPN bipolar transistor of claim 1, wherein the P-type semiconductor structure comprises:
a P-type semiconductor substrate; and
a P-type epitaxial layer form on the semiconductor substrate.

5. The vertical NPN bipolar transistor of claim 4, wherein the P-type semiconductor structure further comprises a P-type buried layer formed on the semiconductor substrate and under the P-type epitaxial layer.

6. A method for forming a vertical NPN bipolar transistor on a P-type semiconductor structure comprising:
forming an N-well formed in the P-type semiconductor structure, the N-well forming the collector region;
defining active areas on the P-type semiconductor structure, the active areas being covered by a nitride mask and including at least a first active area in which the base and emitter regions are formed;
patterning a P-type field mask to define areas on the semiconductor structure for receiving a P-type doping, the P-type field mask having an opening corresponding to the base region and encompassing the first active area;
forming P-type field doped regions using the P-type field mask and the nitride mask;
forming a field oxide layer using the nitride mask, the field oxide layer surrounding the active areas including the first active area, a first P-type region being formed underneath the field oxide layer and around the edge of the first active area;
forming a second P-type region in the N-well and in the first active area, the second P-type region forming the base region, the first P-type region having a doping concentration higher than the second P-type region;
forming a first N-type region in the second P-type region, the first N-type region being heavily doped and forming the emitter region;
forming a third P-type region in the second P-type region, the third P-type region being heavily doped and forming the base contact region; and
forming a second N-type region in the N-well, the second N-type region being heavily doped and forming the collector contact region.
